(19) United States
(12) Patent Application Publication
(10) Pub. No.: US 2025/0008749 A1
(43) Pub. Date: Jan. 2, 2025

(54) SEMICONDUCTOR PACKAGE AND METHOD OF MANUFACTURING THE SEMICONDUCTOR PACKAGE

(71) Applicant: Samsung Electronics Co., Ltd., Suwon-si (KR)

(72) Inventors: Hyundong LEE, Suwon-si (KR); Youngmin KIM, Suwon-si (KR); Joonseok OH, Suwon-si (KR); Sangyun LEE, Suwon-si (KR); Changbo LEE, Suwon-si (KR)

(73) Assignee: Samsung Electronics Co., Ltd., Suwon-si (KR)

(21) Appl. No.: 18/615,116

(22) Filed: Mar. 25, 2024

(30) Foreign Application Priority Data
Jun. 28, 2023 (KR) 10-2023-0083416

(51) Int. Cl. H10B 80/00; H01L 23/00; H01L 23/31; H01L 23/538; H01L 25/065; H01L 25/10

(52) U.S. Cl. CPC H10B 80/00; H01L 23/5385; H01L 23/5386; H01L 24/08; H01L 25/0652; H01L 25/18; H01L 24/16; H01L 2224/08225; H01L 2224/16145; H01L 2224/16227

(57) ABSTRACT

A semiconductor package includes a substrate structure having a bridge chip therein; a semiconductor memory device on a first upper surface of the substrate structure and electrically connected to the bridge chip; and a semiconductor logic device on the first upper surface of the substrate structure and spaced apart from the semiconductor memory device, and the semiconductor logic device electrically connected to the bridge chip. The semiconductor memory device may include a redistribution wiring layer on the substrate structure and having a plurality of redistribution wirings; a plurality of buffer dies on a second upper surface of the redistribution wiring layer and electrically connected to the bridge chip through the plurality of redistribution wirings; and a plurality of semiconductor chips sequentially stacked on each of the plurality of buffer dies and electrically connected to the plurality of buffer dies.

### PRIORITY STATEMENT

This application claims priority under 35 U.S.C. § 119 to Korean Patent Application No. 10-2023-0083416, filed on Jun. 28, 2023 in the Korean Intellectual Property Office (KIPO), the contents of which are herein incorporated by reference in their entirety.

### BACKGROUND

### 1. Field

The present disclosure relates to semiconductor packages and a method of manufacturing semiconductor packages. More particularly, the present disclosure relates to semiconductor packages including a plurality of different chips stacked on one another and a method of manufacturing the same.

### 2. Description of the Related Art

Semiconductor memory devices such as high bandwidth memory (HBM) may include a plurality of chips sequentially stacked on a package substrate. The number of the stacked chips may be limited due to thickness constraints. The semiconductor memory devices may be arranged in a horizontal direction on the package substrate and may be electrically connected to a semiconductor logic device through bridge chips (Si-Bridge chips). In order to electrically connect the semiconductor memory devices to the semiconductor logic device, the same number of bridge chips as the semiconductor memory devices are required. When the number of the bridge chips increases, production costs and process times may increase, and space limitations may occur.

### SUMMARY

Example embodiments provide a semiconductor package including a semiconductor memory device having a structure that electrically connects a plurality of semiconductor chips to a semiconductor logic chip through one bridge chip.

Example embodiments provide a method of manufacturing the semiconductor package.

Embodiments of the inventive concepts provide a semiconductor package that includes a substrate structure having a first upper surface and a first lower surface opposite to the first upper surface, the substrate structure having at least one bridge chip therein; a semiconductor memory device on the first upper surface of the substrate structure and electrically connected to the at least one bridge chip; and a semiconductor logic device on the first upper surface of the substrate structure and spaced apart from the semiconductor memory device, and the semiconductor logic device electrically connected to the at least one bridge chip. The semiconductor memory device includes a redistribution wiring layer having a second upper surface and a second lower surface opposite to the second upper surface, the redistribution wiring layer on the substrate structure, and the redistribution wiring layer having a plurality of redistribution wirings; a plurality of buffer dies on the second upper surface of the redistribution wiring layer and electrically connected to the at least one bridge chip through the plurality of redistribution wirings; and a plurality of semiconductor chips sequentially stacked on each of the plurality of buffer dies and electrically connected to the plurality of buffer dies.

Embodiments of the inventive concepts further provide a semiconductor package that includes a substrate structure having a first upper surface and a first lower surface opposite to the first upper surface, the substrate structure having at least one bridge chip therein; a semiconductor logic device on the first upper surface of the substrate structure and electrically connected to the at least one bridge chip; and a semiconductor memory device on the first upper surface of the substrate structure and spaced apart from the semiconductor logic device, the semiconductor memory device electrically connected to the semiconductor logic device through the at least one bridge chip. The semiconductor memory device includes a redistribution wiring layer having a second upper surface and a second lower surface opposite to the second upper surface and having a plurality of redistribution wirings; a plurality of buffer dies on the second upper surface of the redistribution wiring layer and electrically connected to the at least one bridge chip through the plurality of redistribution wirings; and a plurality of semiconductor chips sequentially stacked on each of the plurality of buffer dies and electrically connected to the plurality of buffer dies.

Embodiments of the inventive concepts still further provide a semiconductor package that includes a substrate structure having a first upper surface and a first lower surface opposite to the first upper surface, the substrate structure having a bridge chip therein; a semiconductor memory device on the first upper surface of the substrate structure; and a semiconductor logic device on the first upper surface of the substrate structure and spaced apart from the semiconductor memory device, and the semiconductor logic device electrically connected to the semiconductor memory device through the bridge chip. The semiconductor memory device includes a redistribution wiring layer having a second upper surface and a second lower surface opposite to the second upper surface, the redistribution wiring layer on the substrate structure, and the redistribution wiring layer having a plurality of redistribution wirings; a plurality of buffer dies on the second upper surface of the redistribution wiring layer and electrically connected to the bridge chip through the plurality of redistribution wirings; a plurality of semiconductor chips sequentially stacked on each of the plurality of buffer dies and electrically connected to the plurality of buffer dies; and a sealing member covering the plurality of buffer dies and the plurality of semiconductor chips on the redistribution wiring layer.

Embodiments of the inventive concepts also provide a semiconductor package that may include a substrate structure having a first upper surface and a first lower surface opposite to first upper surface and having at least one bridge chip therein; a semiconductor memory device on the first upper surface of the substrate structure and electrically connected to the at least one bridge chip; and a semiconductor logic device on the first upper surface of the substrate structure and spaced apart from the semiconductor memory device, and the semiconductor logic device electrically connected to the at least one bridge chip. The semiconductor memory device may include a redistribution wiring layer having a second upper surface and a second lower surface opposite to the second upper surface, the redistribution wiring layer on the substrate structure, and the redistribution wiring layer having a plurality of redistribution wirings; a plurality of buffer dies on the second upper surface of the redistribution wiring layer and electrically connected to the at least one bridge chip through the plurality of redistribution wirings; and a plurality of semiconductor chips sequentially stacked on each of the plurality of buffer dies and electrically connected to the plurality of buffer dies.

Accordingly, the semiconductor memory device may include the plurality of the buffer dies and the plurality of the semiconductor chips on the redistribution wiring layer. The plurality of buffer dies may be electrically connected to the bridge chip through the plurality of redistribution wirings. Since the redistribution wiring layer electrically connects the plurality of buffer dies to the bridge chip through the plurality of redistribution wirings, the plurality of buffer dies may be electrically connected to the semiconductor logic device through one bridge chip.

Since the semiconductor package electrically connects the semiconductor logic device and the plurality of buffer dies through one bridge chip, an additional bridge chip corresponding each of the plurality of buffer dies may be unnecessary. Because the additional bridge chips are unnecessary, production costs and process time for producing the additional bridge chips may be reduced or not be required. Because the semiconductor package needs one bridge chip, space utilization within the semiconductor package may be increased.

### BRIEF DESCRIPTION OF THE DRAWINGS

Example embodiments will be more clearly understood from the following detailed description taken in conjunction with the accompanying drawings. FIGS. 1 to 9 represent non-limiting, example embodiments as described herein.

FIG. 1 is a plan view illustrating a semiconductor package in accordance with some example embodiments of the inventive concepts.

FIG. 2 is a cross-sectional view taken along the line A-A′ in FIG. 1.

FIG. 3 is a cross-sectional view illustrating a semiconductor memory device in FIG. 2.

FIGS. 4, 5, 6, 7, 8 and 9 are views illustrating a method of manufacturing a semiconductor package in accordance with some example embodiments.

### DETAILED DESCRIPTION

Hereinafter, example embodiments will be explained in detail with reference to the accompanying drawings.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

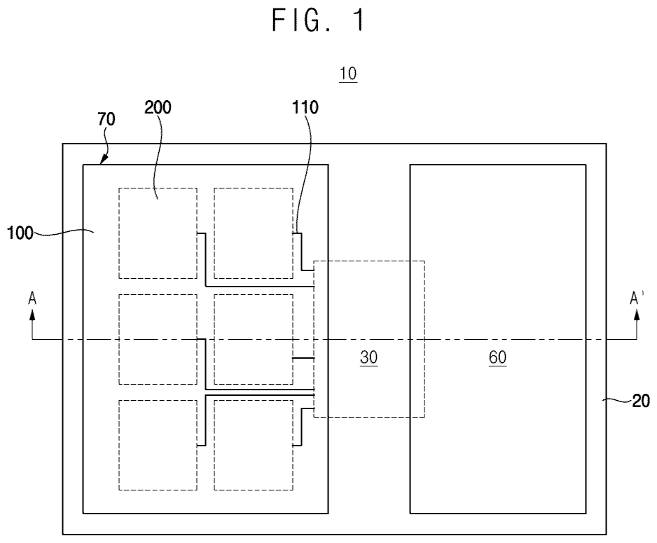

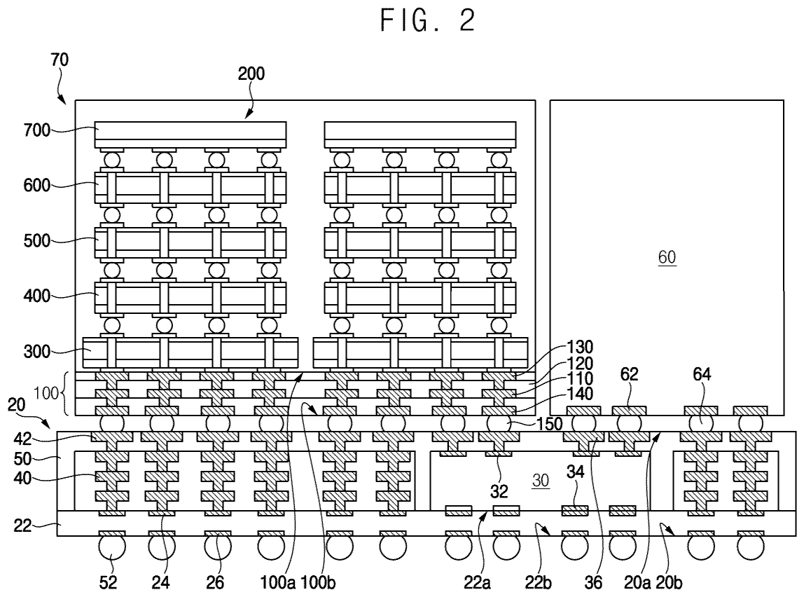

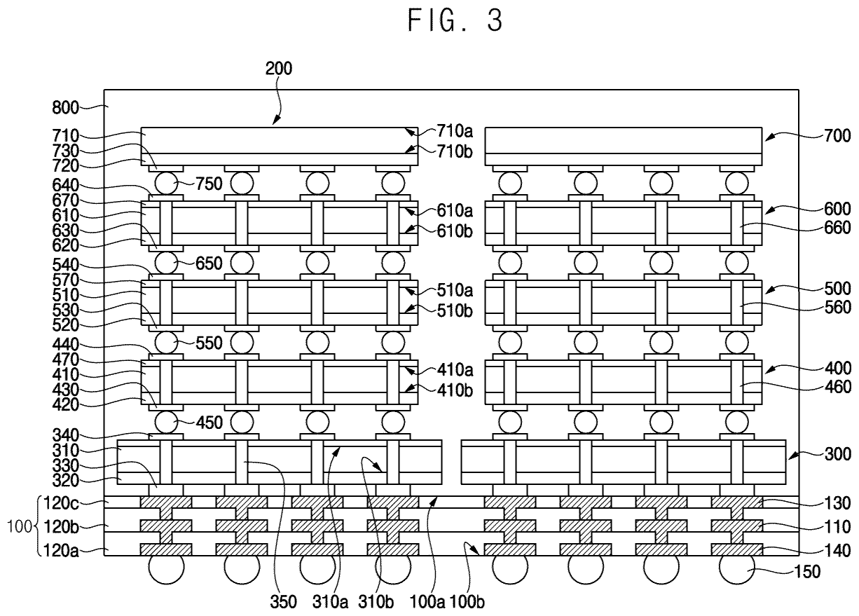

FIG. 1 is a plan view illustrating a semiconductor package in accordance with example embodiments. FIG. 2 is a cross-sectional view taken along the line A-A′ in FIG. 1. FIG. 3 is a cross-sectional view illustrating a semiconductor memory device in FIG. 2.

Referring to FIGS. 1 to 3, a semiconductor package 10 may include a substrate structure 20 having at least one bridge chip 30, a semiconductor memory device 70 mounted on the substrate structure 20, and a semiconductor logic device 60 mounted on the substrate structure 20 to be spaced apart from the semiconductor memory device 70. The semiconductor memory device 70 and the semiconductor logic device 60 may be electrically connected to each other by the bridge chip 30.

In some example embodiments, the semiconductor package 10 may be a memory module having a stacked chip structure in which a plurality of dies (chips) are stacked. For example, the semiconductor logic device 60 may be an ASIC as a host such as a CPU, GPU, or SoC. The semiconductor memory device 70 may include a high bandwidth memory (HBM) device, dynamic random access memory (DRAM), etc.

A planar area of the semiconductor logic device 60 may be smaller than a planar area of the substrate structure 20. When viewed from plan view, the semiconductor logic device 60 may be disposed within an area of the substrate structure 20. When viewed from the plan view, at least a portion of the semiconductor logic device 60 may overlap at least a portion of the bridge chip 30 that is provided within the substrate structure 20.

A planar area of the semiconductor memory device 70 may be smaller than the planar area of the substrate structure 20. When viewed from the plan view, the semiconductor memory device 70 may be disposed within the area of the substrate structure 20. When viewed from the plan view, at least a portion of the semiconductor memory device 70 may overlap at least a portion of the bridge chip 30 that is provided within the substrate structure 20.

In some example embodiments, the substrate structure 20 may have a first upper surface 20a and a first lower surface 20b opposite to the first upper surface 20a. The substrate structure 20 may include a semiconductor substrate 22, a plurality of conductive structures 40 provided on the semiconductor substrate 22, a bridge chip 30 provided on the semiconductor substrate 22, a plurality of first external connection pads 36 electrically connected to the bridge chip 30, and a plurality of second external connection pads 42 electrically connected to the conductive structures 40. The substrate structure 20 may further include a second sealing member 50 covering the plurality of conductive structures 40 and the bridge chip 30 on the semiconductor substrate 22. The substrate structure 20 may further include a plurality of external connection bumps 52.

The semiconductor substrate 22 may be a substrate having an upper surface 22a and a lower surface 22b opposite to each other. For example, the semiconductor substrate 22 may include a printed circuit board (PCB), a flexible board, a tape board, etc. The printed circuit board may be a multilayer circuit board having vias and various circuits therein.

First substrate pads 24 may be provided on the upper surface 22a of the semiconductor substrate 22 to be connected to a plurality of wires (not shown). The wires may extend from the upper surface 22a of the semiconductor substrate 22 or within the semiconductor substrate 22. The first substrate pads 24 may be respectively connected to end portions of the wires.

The wires may include a power wire or a ground wire as a power net for supplying power to electronic components mounted on the semiconductor substrate 22. The first substrate pads 24 may include a power pad or a ground pad connected to the power wire or the ground wire. The first substrate pads 24 may further include a plurality of substrate signal wires and substrate signal pads for transmitting data signals to the electronic components.

Although only some substrate pads are illustrated in the figures, it will be understood that the number, shape, and arrangement of the substrate pads are provided as examples, and the inventive concepts are not limited thereto. Description of the wirings as well as the substrate pads, and illustration concerning the above elements, will be omitted.

Second substrate pads 26 may be provided on the lower surface 22b of the semiconductor substrate 22 to be connected to the plurality of wires. The second substrate pads 26 may be respectively connected to other end portions of the wires that are opposite to the end portions of the wires. External connection bumps 52 may be disposed on the second substrate pads 26 of the semiconductor substrate 22 for electrical connection with an external device. For example, the external connection bumps 52 may be solder balls. The semiconductor package 10 may be mounted on a module substrate (not illustrated) using the solder balls to form a memory module.

The conductive structures 40 may be provided on the first substrate pads 24 of the semiconductor substrate 22. The conductive structures 40 may be arranged on the semiconductor substrate 22 to be spaced apart from the bridge chip 30. The conductive structures 40 may be sequentially stacked on the first substrate pads 24 of the semiconductor substrate 22. The conductive structures 40 may electrically connect the semiconductor substrate 22 to the semiconductor logic device 60 and the semiconductor memory device 70.

For example, the conductive structures 40 may be electrically connected to the first substrate pads 24 of the semiconductor substrate 22. The conductive structures 40 may be electrically connected to the second external connection pads 42. The conductive structures 40 may provide a signal movement path for electrically connecting the semiconductor substrate 22 and the second external connection pads 42.

For example, the conductive structures 40 may include pillars, bumps, etc. The conductive structures 40 may include nickel (Ni), antimony (Sb), bismuth (Bi), zinc (Zn), indium (In), palladium (Pd), platinum (Pt), aluminum (Al), copper (Cu), molybdenum (Mo), titanium (Ti), gold (Au), silver (Ag), chromium (Cr), tin (Sn), and an alloy thereof. The conductive structures 40 may be formed by a plating process, an electroless plating process, a vapor deposition process, etc.

The bridge chip 30 may be arranged on the upper surface 22a of the semiconductor substrate 22 to be spaced apart from the conductive structures 40. The bridge chip 30 may be electrically connected to the first substrate pads 24 of the semiconductor substrate 22. The first external connection pads 36 may be disposed on the bridge chip 30. The bridge chip 30 may be electrically connected to the first external connection pads 36.

The bridge chip 30 may include a silicon bridge chip (Si-Bridge chip). The bridge chip 30 may function as an interposer and may electrically connect the semiconductor logic device 60 and the semiconductor memory device 70 to each other. The bridge chip 30 may provide high-density interconnection between the semiconductor logic device 60 and the semiconductor memory device 70. For example, the number of bridge chips 30 may be a first number, or in other words, there may be a first number of bridge chips 30.

In some example embodiments, the second sealing member 50 may be formed on the semiconductor substrate 22 to protect the plurality of conductive structures 40 and the bridge chip 30 from the outside. The second sealing member 50 may expose the first external connection pads 36 and the second external connection pads 42 from the first upper surface 20a of the substrate structure 20. For example, the second sealing member may include an epoxy mold compound (EMC).

In some example embodiments, the semiconductor logic device 60 may be mounted on the first upper surface 20a of the substrate structure 20. The semiconductor logic device 60 may be mounted on the substrate structure 20 to be spaced apart from the semiconductor memory device 70.

The semiconductor logic device 60 may be mounted on the substrate structure 20 using a flip chip bonding method. For example, the semiconductor logic device 60 may be mounted on the substrate structure 20 such that an active surface on which logic chip pads 62 are formed faces the substrate structure 20.

The logic chip pads 62 of the semiconductor logic device 60 may be electrically connected to the first external connection pads 36 and the second external connection pads 42 of the substrate structure 20 by logic conductive bumps 64 as conductive connection members. The semiconductor logic device 60 may be electrically connected to the bridge chip 30 through the first external connection pads 36. The semiconductor logic device 60 may be electrically connected to the conductive structures 40 through the second external connection pads 42. For example, the logic conductive bumps 64 may include micro bumps (uBumps).

For example, the semiconductor logic device 60 may include a semiconductor device such as a logic device. The logic device may include central processing units (CPUs), graphic processing units (GPUs), micro processing units (MPUs), micro control units (MCUs), application processors (APs), etc.

In some example embodiments, the semiconductor memory device 70 may be mounted on the first upper surface 20a of the substrate structure 20. The semiconductor memory device 70 may be mounted on the substrate structure 20 to be spaced apart from the semiconductor logic device 60.

The semiconductor memory device 70 may be mounted on the substrate structure 20 using a flip chip bonding method. For example, the semiconductor memory device 70 may be mounted on the substrate structure 20 such that the redistribution wiring layer 100 faces the substrate structure 20. The semiconductor memory device 70 may be electrically connected to the first external connection pads 36 and the second external connection pads 42 of the substrate structure 20 by solder bumps 150 as conductive connection members. The semiconductor memory device 70 may be electrically connected to the bridge chip 30 through the first external connection pads 36. The semiconductor memory device 70 may be electrically connected to the conductive structures 40 through the second external connection pads 42.

Hereinafter, the semiconductor memory device 70 will be described in more detail.

Referring to FIG. 3, the semiconductor memory device 70 may include a redistribution wiring layer 100 having a plurality of redistribution wirings 110 and a plurality of solder bumps 150, and a plurality of semiconductor devices 200 mounted on the redistribution wiring layer 100.

For example, the number of the semiconductor devices 200 may be a second number, or in other words, there may be a second number of the semiconductor devices 200. The first number of the bridge chips 30 may be smaller than the second number of the semiconductor devices 200. Accordingly, one bridge chip 30 may electrically connect two or more semiconductor devices 200 to the semiconductor logic device 60.

In some example embodiments, the redistribution wiring layer 100 may include a plurality of insulating layers 120 and the redistribution wirings 110 provided in the insulating layers 120. The redistribution wiring layer 100 may include a second upper surface 100a and a second lower surface 100b opposite to each other. The redistribution wiring layer 100 may include a plurality of first redistribution pads 130 that are exposed from an upper surface of the redistribution wiring layer 100, e.g., the second upper surface 100a, and a plurality of second redistribution pads 140 that are exposed from a lower surface of the redistribution wiring layer 100, e.g., the second lower surface 100b.

The insulating layers may include a polymer, a dielectric layer, etc. The insulating layers may be formed by a vapor deposition process, spin coating process, etc. The redistribution wirings may be formed by a plating process, an electroless plating process, a vapor deposition process, etc. The redistribution wirings may electrically connect the first redistribution pads 130 and the second redistribution pads 140.

In some example embodiments, the insulating layers 120 may cover the redistribution wirings 110. A first insulating layer 120a may be provided on the second lower surface 100b of the redistribution wiring layer 100, and a third insulating layer 120c may be provided on the second upper surface 100a of the redistribution wiring layer 100.

For example, a plurality of the first redistribution pads 130 may be provided in the third insulating layer 120c. Upper surfaces of the first redistribution pads 130 may be exposed from an upper surface of the third insulating layer 120c, that is, the second upper surface 100a. The third insulating layer 120c may have third openings that expose the upper surfaces of the first redistribution pads 130, respectively.

A plurality of the second redistribution pads 140 may be provided in the first insulating layer 120a. Lower surfaces of the second redistribution pads 140 may be exposed from a lower surface of the first insulating layer 120a, that is, the second lower surface 100b. The first insulating layer 120a may have first openings that expose upper surfaces of the second redistribution pads 140, respectively.

The redistribution wirings 110 may be formed on the first insulating layer 120a and may be contact the second redistribution pads 140 through the first openings. The redistribution wirings 110 may be electrically connected to the second redistribution pads 140. The second insulating layer 120b may be formed on the first insulating layer 120a and may have second openings that expose the redistribution wirings 110.

The first redistribution pads 130 may be formed on the second insulating layer 120b and may contact the redistribution wirings 110 through the second openings. The third insulating layer 120c may be formed on the second insulating layer 120b and may have third openings that expose the first redistribution pads 130. Accordingly, the plurality of first redistribution pads 130 may be exposed from the upper surface of the third insulating layer 120c, that is, the second upper surface 100a.

The first redistribution pads 130, the second redistribution pads 140, and the redistribution wirings 110 may include a metal material. For example, the metal material may include nickel (Ni), antimony (Sb), bismuth (Bi), zinc (Zn), indium (In), palladium (Pd), platinum (Pt), aluminum (Al), and copper. (Cu), molybdenum (Mo), titanium (Ti), gold (Au), silver (Ag), chromium (Cr), tin (Sn), or an alloy thereof.

In some example embodiments, the redistribution wiring layer 100 may be connected to other semiconductor devices through the solder bumps 150 as conductive connection members. The solder bumps 150 may be formed on the second redistribution pads 140, respectively. For example, the solder bumps 150 may include micro bumps (uBumps). The second redistribution pads 140 of the redistribution wiring layer 100 may be electrically connected to the first substrate pads 24 and the second substrate pads 26 of the substrate structure 20 by the solder bumps 150.

In some example embodiments, each of the semiconductor devices 200 may include a buffer die 300 that is electrically connected to the bridge chip 30 through the plurality of redistribution wirings 110, and a plurality of semiconductor chips 400, 500, 600, and 700 sequentially stacked on the buffer die 300.

As illustrated in FIG. 3, the semiconductor memory device 70 may include the redistribution wiring layer 100 having the plurality of redistribution wirings 110 and the plurality of solder bumps 150, and the plurality of semiconductor devices 200 mounted on the redistribution wiring layer 100. In some example embodiments, each of the semiconductor devices 200 may include a high bandwidth memory (HBM) device.

A plurality of the semiconductor chips 400, 500, 600 and 700 may be vertically stacked on the buffer die 300. In some example embodiments, the buffer die 300 and the first to fourth semiconductor chips 400, 500, 600 and 700 may be substantially the same as or similar to each other. In some example embodiments, the buffer die 300 may include a high bandwidth memory (HBM) device. Accordingly, same or like reference numerals will be used to refer to the same or like elements and repeated descriptions of the same elements may be omitted.

In some example embodiments, one semiconductor device 200 is illustrated as including four stacked semiconductor chips 400, 500, 600 and 700, however, some other example embodiments may not be limited thereto. For example, the semiconductor device 200 may include 8, 12, or 16 stacked semiconductor chips.

In some example embodiments, the buffer die 300 includes a buffer substrate 310 having a third upper surface 310a and a third lower surface 310b opposite to each other, lower buffer pads 330 and insulating layer 320 provided on the third lower surface 310b, and upper buffer pads 340 provided on the third upper surface 310a. The buffer die 300 may further include buffer through electrodes 350 that penetrate the buffer substrate 310 and electrically connect the lower buffer pads 330 and the upper buffer pads 340.

The third lower surface 310b of the buffer die 300 may be disposed to face the second upper surface 100a of the redistribution wiring layer 100. The insulating layer 120 of the redistribution wiring layer 100 and the buffer die 300 may be directly bonded to each other. The redistribution wirings 110 of the redistribution wiring layer 100 may extend in the redistribution wiring layer 100 to electrically connect the plurality of buffer dies 300 to one bridge chip 30.

The lower buffer pads 330 may be exposed toward the redistribution wiring layer 100. The lower buffer pads 330 may be bonded to the first redistribution pads 130 of the redistribution wiring layer 100 and electrically connected to the first redistribution pads 130. Accordingly, the lower buffer pads 330 and the first redistribution pads 130 between the buffer die 300 and the redistribution wiring layer 100 may be bonded to each other by copper-copper hybrid bonding (Cu-Cu Hybrid Bonding). For example, pad to pad direct bonding may be formed.

The first semiconductor chip 400 may include a first substrate 410 having a fourth upper surface 410a and a fourth lower surface 410b opposite to each other, first lower chip pads 430 provided on the fourth lower surfaces 410b, first upper chip pads 440 provided on the fourth upper surface 410a, and first conductive bumps 450 provided on the first lower chip pads 430. The first semiconductor chip 400 may further include first through electrodes 460 that penetrate the first substrate 410, and a first protective layer 470 provided on the fourth upper surface 410a.

The fourth upper surface 410a of the first substrate 410 may be an inactive surface, and the fourth lower surface 410b may be an active surface. Circuit patterns may be provided on the fourth lower surface 410b of the first substrate 410. The fourth lower surface 410b may be referred to as a front surface on which the circuit patterns are formed, and the fourth upper surface 410a may be referred to as a backside surface.

For example, the first substrate 410 may be a semiconductor material such as silicon, germanium, silicon-germanium, etc., or a group III-V compound such as gallium phosphide (GaP), gallium arsenide (GaAs), gallium antimonide (GaSb), etc. In some example embodiments, the second substrate 410 may be a silicon-on-insulator (SOI) substrate, or a germanium-on-insulator (GOI) substrate.

The circuit patterns may include transistors, diodes, etc. The circuit patterns may constitute circuit elements. Accordingly, the first semiconductor chip 400 may be a semiconductor device with a plurality of circuit elements formed therein.

In some example embodiments, a first activation layer 420 may be provided on the fourth lower surface 410b of the first substrate 410. The first activation layer 420 may include a chip insulating layer and a plurality of chip redistribution wirings provided in the chip insulating layer. The chip redistribution wirings may be connected to one end portion of the first through electrode 460. The first lower chip pads 430 may be connected to the chip redistribution wirings that are electrically connected to the first through electrodes 460. The chip insulating layer may include silicon oxide, carbon-doped silicon oxide, silicon carbonitride (SiCN), etc.

The first conductive bumps 450 may be provided on the first lower chip pads 430. The first conductive bumps 450 may provide an electrical path for electrically connecting the first semiconductor chip 400 to another semiconductor device. The first semiconductor chip 400 may be mounted on the buffer die 300 via the first conductive bumps 450. For example, the first conductive bumps 450 may include a micro bump (uBump).

The first protective layer 470 may be provided on the fourth upper surface 410a of the first substrate 410. The first protective layer 470 may be formed of an insulating material and may protect the first substrate 410 from the outside. The first protective layer 470 may be formed of an oxide layer or a nitride layer, or may be formed of a double layer of an oxide layer and a nitride layer. The first protective layer 470 may be formed of an oxide layer, for example, a silicon oxide film (SiO₂) using a high-density plasma chemical vapor deposition (HDP-CVD) process.

The first upper chip pads 440 may be formed on the first protective layer 470 and may be electrically connected to the first through electrode 460. The first upper chip pads 440 may be electrically connected to the first through electrode 460 on the other end portion opposite to the one end portion of the first through electrode 460.

The first through electrode 460 may penetrate the first substrate 410 in the vertical direction. One end portion of the first through electrode 460 may be electrically connected to the chip redistribution wirings. The other end portion of the first through electrode 460 may be exposed from the fourth upper surface 410a of the first substrate 410. The first through electrode 460 may be electrically connected to the first upper chip pad 440 through the exposed other end portion.

The first upper chip pads 440, the first lower chip pads 430, and the first through electrodes 460 may include a same metal. For example, the metal may include copper (Cu), aluminum (Al), tungsten, nickel (Ni), molybdenum (Mo), gold (Au), silver (Ag), chromium (Cr), and tin (Sn), titanium (Ti), etc. However, some other example embodiments may not be limited thereto, and the metal may include a material (e.g., gold (Au)) that can be bonded by inter-diffusion of metals by a high-temperature annealing process.

For example, the first semiconductor chip 400 may include a semiconductor device such as a memory device. The first semiconductor chip 400 may include volatile memory devices such as SRAM devices, DRAM devices, etc., and non-volatile memory devices such as flash memory devices, PRAM devices, MRAM devices, RRAM devices, etc.

In some example embodiments, the second semiconductor chip 500 may include a second substrate 510, second upper chip pads 540 provided on a fifth upper surface 510a of the second substrate 510, and second lower chip pads 530 provided on a fifth lower surface 510b of the second substrate 510, and second conductive bumps 550 provided on the second lower chip pads 530. The second semiconductor chip 500 may further include second through electrodes 560 that penetrate the second substrate 510 in the vertical direction, and a second protective layer 570 provided on the fifth upper surface 510a. A second activation layer 520 may be provided on the fifth lower surface 510b of the second substrate 510.

The fifth lower surface 510b of the second substrate 510 may be disposed to face the fourth upper surface 410a of the first substrate 410. The second conductive bumps 550 of the second semiconductor chip 500 may be directly bonded to the first upper chip pads 440 of the first semiconductor chip 400. The second semiconductor chip 500 may be mounted on the first semiconductor chip 400 using a flip chip bonding method. The second lower chip pads 530 of the second semiconductor chip 500 may be electrically connected to the first upper chip pads 440 of the first semiconductor chip 400 by the second conductive bumps 550.

In some example embodiments, the third semiconductor chip 600 may include a third substrate 610, third upper chip pads 640 provided on a sixth upper surface 610a of the third substrate 610, and third lower chip pads 630 provided on a sixth lower surface 610b of the third substrate 610, and third conductive bumps 650 provided on the third lower chip pads 630. The third semiconductor chip 600 may further include third through electrodes 660 that penetrate the third substrate 610 in the vertical direction, and a third protective layer 670 provided on the sixth upper surface 610a. A third activation layer 620 may be provided on the sixth lower surface 610b of the third substrate 610. The third semiconductor chip 600 may be mounted on the second semiconductor chip 500 using a flip chip bonding method.

The fourth semiconductor chip 700 may include a fourth substrate 710 including a seventh upper surface 710a and a seventh lower surface 710b, and fourth lower chip pads 730 provided on the seventh lower surface 710b of the fourth substrate 710. A fourth activation layer 720 may be provided on the seventh lower surface 710b of the fourth substrate 710. The fourth semiconductor chip 700 may include fourth conductive bumps 750 provided on the fourth lower chip pads 730. The fourth semiconductor chip 700 may be mounted on the third semiconductor chip 600 using a flip chip bonding method.

In some example embodiments, the semiconductor memory device 70 may include a first sealing member 800 covering the buffer die 300 and the first to fourth semiconductor chips 400, 500, 600 and 700 on the redistribution wiring layer 100.

For example, the first sealing member 800 may include an epoxy mold compound (EMC). The first sealing member 800 may include UV resin, polyurethane resin, silicone resin, silica filler, etc.

As mentioned above, the semiconductor memory device 70 may include a plurality of the buffer dies 300 and a plurality of the semiconductor chips 400, 500, 600, and 700 on the redistribution wiring layer 100. The plurality of buffer dies 300 may be electrically connected to the bridge chip 30 through the plurality of redistribution wirings 110. Since the redistribution wiring layer 100 electrically connects the plurality of buffer dies 300 to the bridge chip 30 through the plurality of redistribution wirings 110, the plurality of buffer dies 300 may be electrically connected to the semiconductor logic device 60 through one bridge chip 30.

Since the semiconductor package 10 electrically connects the semiconductor logic device 60 and the plurality of buffer dies 300 through one bridge chip 30, an additional bridge chip corresponding each of the plurality of buffer dies 300 may be unnecessary. Because the additional bridge chips are unnecessary, production costs and process time for producing the additional bridge chips may be reduced or not be required. Because the semiconductor package 10 includes one bridge chip 30, space utilization within the semiconductor package 10 may be increased.

Hereinafter, a method of manufacturing the semiconductor package of FIG. 1 will be described.

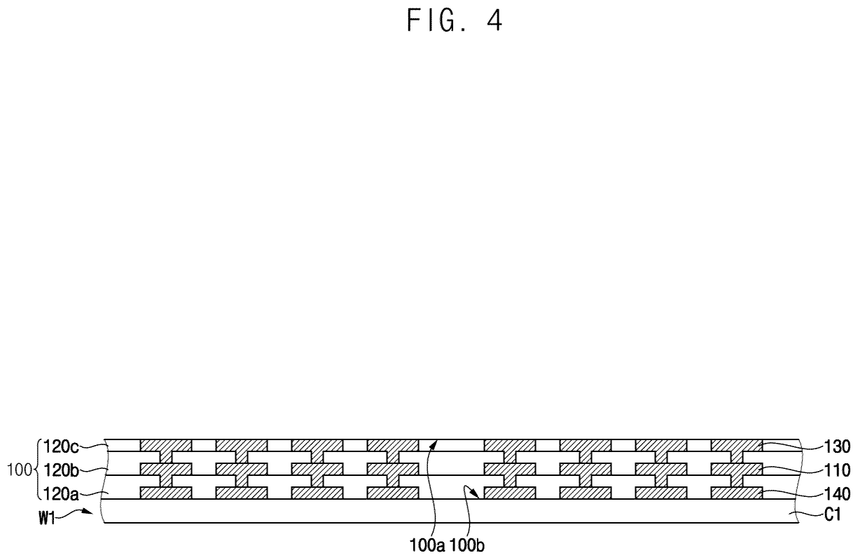

FIGS. 4 to 9 are views illustrating a method of manufacturing a semiconductor package in accordance with some example embodiments.

Referring to FIG. 4, first, a semiconductor wafer W1 having redistribution wiring layer 100 on a carrier substrate C1 may be provided.

First, second redistribution pads 140 may be formed on the carrier substrate C1, and a first insulating layer 120a may be formed on the second redistribution pads 140. Then, the first insulating layer 120a may be patterned to form first openings that expose the second redistribution pads 140.

For example, the first insulating layer 120a may include a polymer, a dielectric layer, etc. For example, the first insulating layer 120a may include polyimide (PI), lead oxide (PbO), polyhydroxystyrene (PHS), NOVOLAC® (an industrial grade epoxy), etc. The first insulating layer 120a may be formed by a vapor deposition process, spin coating process, etc.

Redistribution wirings 110 may be formed on the first insulating layer 120a to be electrically connected to the second redistribution pads 140 through the first openings respectively.

The redistribution wirings 110 may be formed by forming a seed layer on a portion of the first insulating layer 120a and in the first openings, patterning the seed layer and performing an electrolytic plating process. Accordingly, at least portions of the redistribution wires 110 may directly contact the second redistribution pads 140 through the first openings.

For example, the redistribution wiring may include aluminum (Al), copper (Cu), tin (Sn), nickel (Ni), gold (Au), platinum (Pt), or an alloy thereof.

Then, after a second insulating layer 120b is formed on the first insulating layer 120a to cover the redistribution wirings 110, the second insulating layer 120b may be patterned to form second openings that expose the redistribution wirings 110. First redistribution pads 130 may be formed on the second insulating layer 120b to be electrically connected to the redistribution wirings 110 through the second openings.

Then, after a third insulating layer 120c is formed on the second insulating layer 120b to cover the first redistribution pads 130, the third insulating layer 120c may be patterned to form third openings that expose the first redistribution pads 130 respectively.

Accordingly, the redistribution wiring layer 100 including a plurality of insulating layers 120 and the redistribution wirings 110 provided in the insulating layers may be formed on the carrier substrate C1.

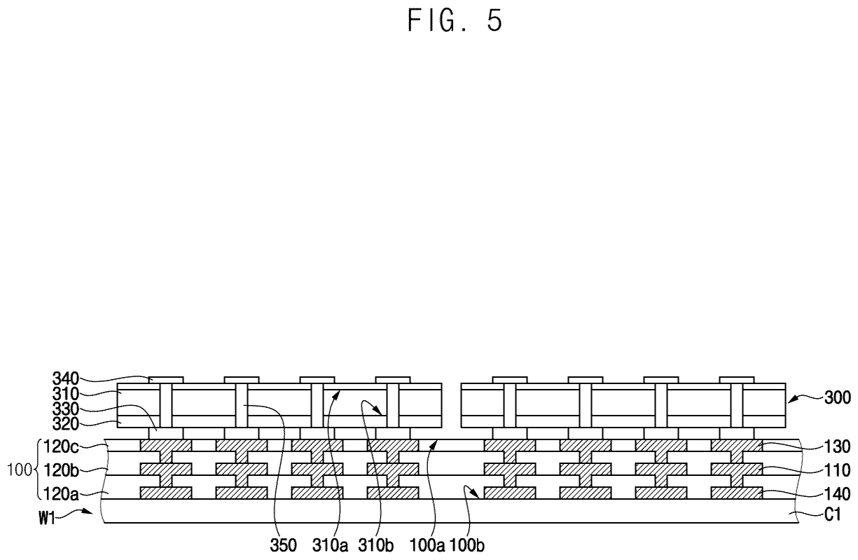

Referring to FIG. 5, a plurality of buffer dies 300 may be attached on the redistribution wiring layer 100 of the semiconductor wafer W1.

In some example embodiments, the buffer dies 300 may be directly bonded to the insulating layer 120 of the redistribution wiring layer 100. Lower buffer pads 330 of the buffer dies 300 may be bonded to the first redistribution pads 130 of the redistribution wiring layer 100 and may be electrically connected to the first redistribution pads 130. Accordingly, the lower buffer pads 330 and the first redistribution pads 130 between the buffer die 300 and the redistribution wiring layer 100 may be bonded to each other by copper-copper hybrid bonding (Cu-Cu Hybrid Bonding). For example, pad to pad direct bonding may be formed.

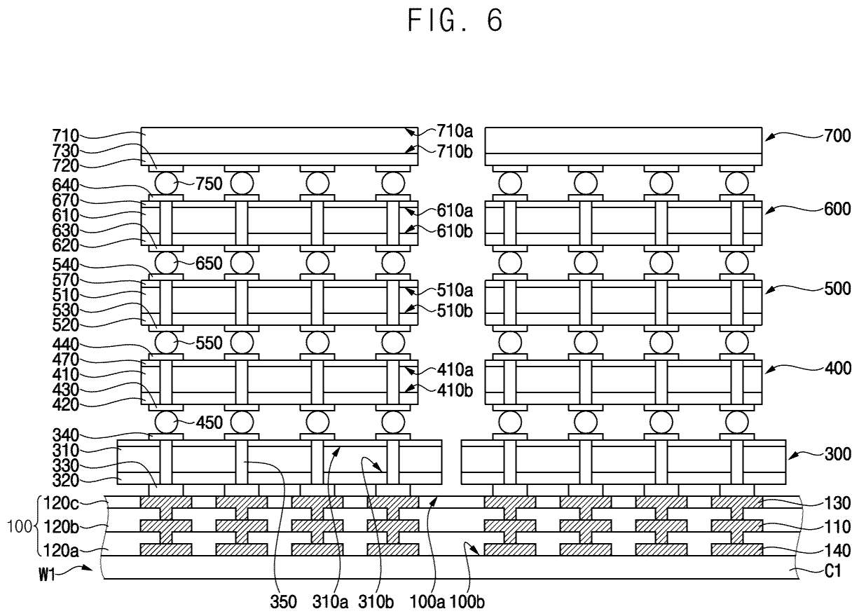

Referring to FIG. 6, first semiconductor chips 400 may be attached to each of the plurality of buffer dies 300. The first semiconductor chip 400 may be attached to a third upper surface 310a of the buffer die 300 by performing a thermal compression process at a desired (and/or alternatively predetermined) temperature (e.g., about 400° C. or less). By the thermal compression process, the first semiconductor chip 400 and the buffer die 300 may be bonded to each other. That is, first conductive bumps 450 of the first semiconductor chip 400 may be bonded to the upper buffer pads 340 provided on the third upper surface 310a of the buffer die 300, respectively. In the thermal compression process, an adhesive material may be formed between the buffer die 300 and the first semiconductor chip 400. For example, the adhesive material may include a non-conductive film (NCF) material.

Second semiconductor chips 500 formed by the same processes as the first semiconductor chips 400 may be attached to the first semiconductor chips 400, respectively. Similarly, third semiconductor chips 600 may be attached on the second semiconductor chips 500, respectively. Fourth semiconductor chips 700 may be attached on the third semiconductor chips 600, respectively. The first to fourth semiconductor chips 400, 500, 600 and 700 may be attached to the semiconductor wafer W1 by a flip chip bonding method.

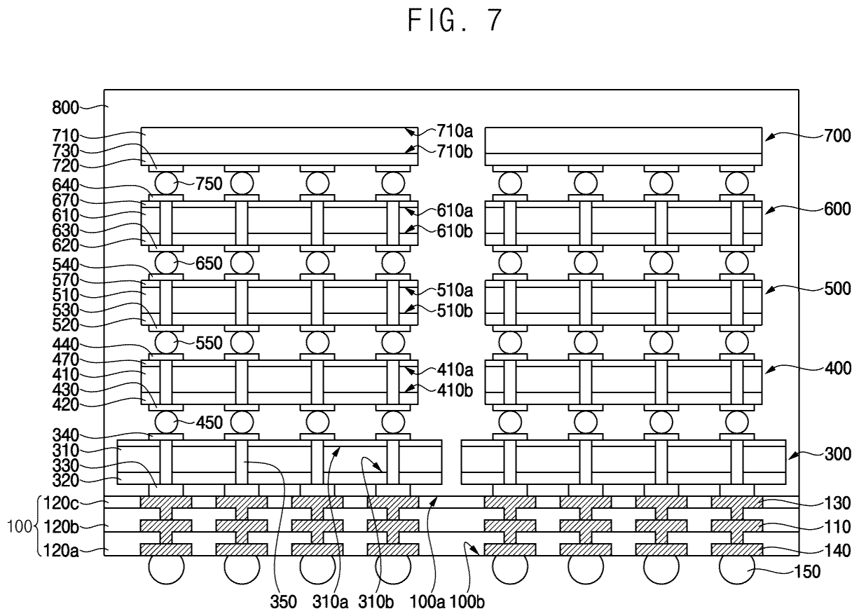

Referring to FIG. 7, first, a first sealing member 800 may be formed on the semiconductor wafer W1 to cover the stacked structures of the buffer die 300 and the first to fourth semiconductor chips 400, 500, 600 and 700, and solder bumps 150 may be formed on the second redistribution pads 140 of the redistribution wiring layer 100, respectively.

In some example embodiments, the first sealing member 800 may be formed to fill spaces between the buffer die 300 and the first to fourth semiconductor chips 400, 500, 600 and 700 on the semiconductor wafer W1. The first sealing member 800 may be formed to surround the buffer die 300 and the first to fourth semiconductor chips 400, 500, 600 and 700. The first sealing member 800 may be formed by a dispensing process or a spin coating process. For example, the first sealing member 800 may include a thermosetting resin, etc.

The solder bumps 150 may be formed on the second lower surface 100b of the redistribution wiring layer 100. The solder bumps 150 may be formed on the second redistribution pads 140 of the redistribution wiring layer 100, respectively.

For example, after a first photoresist pattern having first temporary openings is formed on the second lower surface 100b of the redistribution wiring layer 100, the first temporary openings of the first photoresist pattern may be filled with a conductive material, the first photoresist pattern may be removed and a reflow process may be performed to form the solder bumps 150. For example, the conductive material may be formed through a plating process. Alternatively, the solder bumps 150 may be formed by screen printing, deposition, etc. For example, the solder bumps 150 may include a micro bump (uBump).

Then, the semiconductor wafer W1 and the first sealing member 800 may be cut along a scribe lane region to form the semiconductor memory device 70 of FIG. 1. The semiconductor wafer W1 and the first sealing member 800 may be cut by a dicing process.

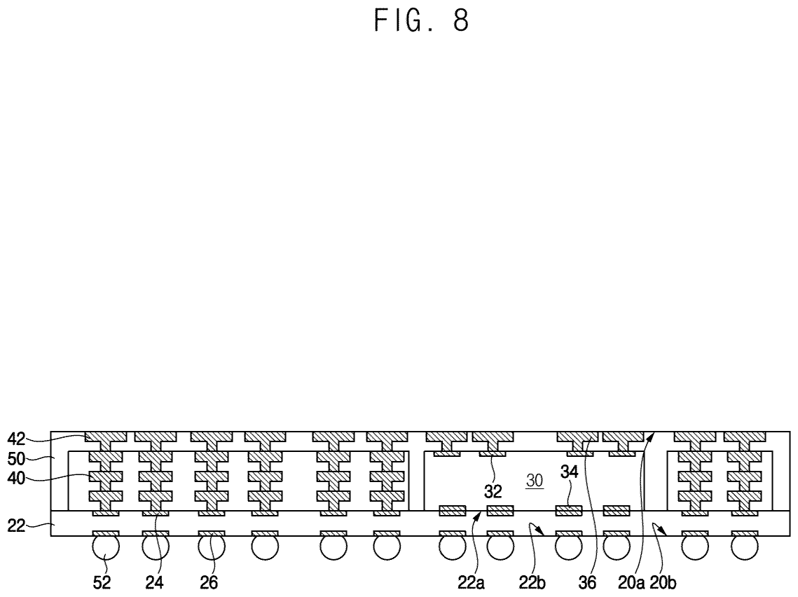

Referring to FIG. 8, a substrate structure 20 having a bridge chip 30 provided therein may be formed.

In some example embodiments, first, the bridge chip 30 may be placed on a semiconductor substrate 22, and a plurality of conductive structures 40 may be formed on the semiconductor substrate 22.

First substrate pads 24 may be provided on an upper surface 22a of the semiconductor substrate 22 to be electrically connected to a plurality of wires formed therein, and second substrate pads 26 may be provided on a lower surface 22b of the semiconductor substrate 22 to be electrically connected to the plurality of wires.

The bridge chip 30 may be mounted on the semiconductor substrate 22 such that second bridge chip pads 34 face the semiconductor substrate 22. The second bridge chip pads 34 may be bonded to the first substrate pads 24 of the semiconductor substrate 22 and may be electrically connected to the first substrate pads 24. Accordingly, the second bridge chip pads 34 and the first substrate pads 24 between the bridge chip 30 and the semiconductor substrate 22 may be bonded to each other by copper-copper hybrid bonding (Cu-Cu Hybrid Bonding). For example, pad to pad direct bonding may be formed.

The plurality of conductive structures 40 may be formed on the semiconductor substrate 22. The conductive structures 40 may be formed to be electrically connected to the first substrate pads 24 exposed from the upper surface 22a of the semiconductor substrate 22. The conductive structures 40 may be formed to be sequentially stacked on the semiconductor substrate 22.

For example, a first photoresist layer may be formed on the semiconductor substrate 22 by a deposition process, and through openings may be formed to penetrate the first photoresist layer in a vertical direction. The conductive structures 40 may be formed in the through openings by a first plating process. For example, the conductive structures 40 may be formed by a plating process, an electroless plating process, a vapor deposition process, etc.

Then, the first photoresist layer may be removed to form the conductive structures 40 that are in contact with the first substrate pads 24. The deposition process and the first plating process may be repeatedly performed to form the stacked conductive structures 40. Alternatively, a connection block having the plurality of conductive structures 40 may be formed, and the connection block may be disposed on the semiconductor substrate 22.

Then, a second sealing member 50 may be formed on the semiconductor substrate 22 to cover the bridge chip 30 and the conductive structures 40, and the second sealing member 50 may be patterned to form second through openings that expose first bridge chip pads 32 of the bridge chip 30 and the conductive structures 40.

The second sealing member 50 may be formed on the semiconductor substrate 22 to protect the plurality of conductive structures 40 and the bridge chip 30 from the outside. For example, the second sealing member may include an epoxy mold compound (EMC).

Then, a second plating process may be performed to form first external connection pads 36 and second external connection pads 42 in the second through openings. The first external connection pads 36 may be formed on the first bridge chip pads 32 of the bridge chip 30, respectively. The second external connection pads 42 may be formed on the conductive structures 40, respectively.

Then, external connection bumps 52 may be formed on the second substrate pads 26 of the semiconductor substrate 22. For example, after a second photoresist pattern having second temporary openings is formed on the lower surface 22b of the semiconductor substrate 22, the second temporary openings of the second photoresist pattern may be filled with a conductive material, the second photoresist pattern may be removed and a reflow process may be performed to form the external connection bumps 52. For example, the conductive material may be formed by a plating process. Alternatively, the external connection bumps 52 may be formed by screen printing, deposition, etc. For example, the external connection bump 52 may include a C4 bump.

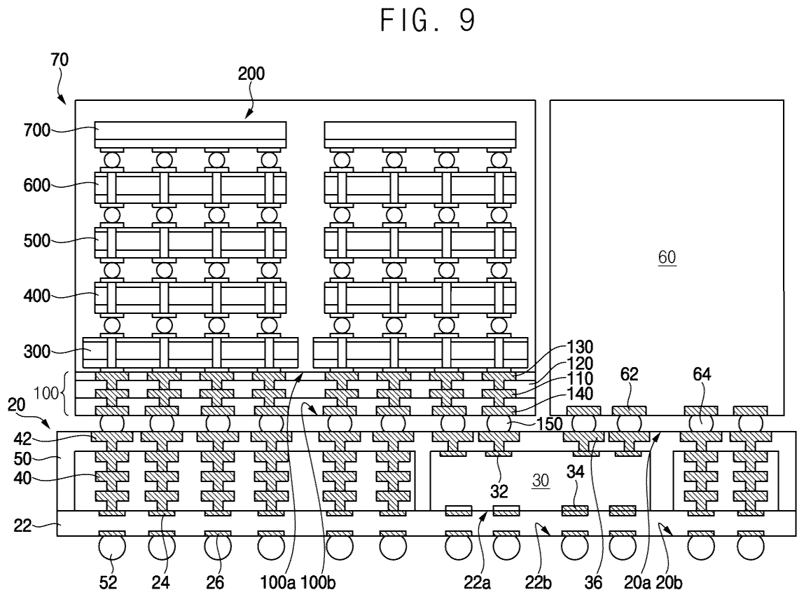

Referring to FIG. 9, a semiconductor logic device 60 may be disposed on the substrate structure 20, and the semiconductor memory device 70 may be disposed on the substrate structure 20 to be spaced apart from the semiconductor logic device 60.

The semiconductor logic device 60 may be mounted on the substrate structure 20 using a flip chip bonding method. For example, the semiconductor logic device 60 may be mounted on the substrate structure 20 such that logic chip pads 62 face the substrate structure 20. The logic chip pads 62 of the semiconductor logic device 60 may be electrically connected to the first external connection pads 36 and the second external connection pads 42 of the substrate structure 20 by logic conductive bumps 64 as conductive connection members.

The semiconductor memory device 70 may be mounted on the substrate structure 20 using a flip chip bonding method. In this case, the semiconductor memory device 70 may be mounted on the substrate structure 20 such that the redistribution wiring layer 100 faces the substrate structure 20. The redistribution wiring layer 100 of the semiconductor memory device 70 may be electrically connected to the first external connection pads 36 and the second external connection pads 42 of the substrate structure 20 by the solder bumps 150 as conductive connection members.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, an application-specific integrated circuit (ASIC), etc.

The foregoing is illustrative of example embodiments and is not to be construed as limiting thereof. Although some example embodiments have been described, those skilled in the art will readily appreciate that many modifications are possible in example embodiments without materially departing from the novel teachings and advantages of the inventive concepts. Accordingly, all such modifications are intended to be included within the scope of example embodiments as defined in the claims.

What is claimed is:

1. A semiconductor package, comprising:
a substrate structure having a first upper surface and a first lower surface opposite to the first upper surface, the substrate structure having at least one bridge chip therein;
a semiconductor memory device on the first upper surface of the substrate structure and electrically connected to the at least one bridge chip; and
a semiconductor logic device on the first upper surface of the substrate structure and spaced apart from the semiconductor memory device, and the semiconductor logic device electrically connected to the bridge chip,
wherein the semiconductor memory device includes
a redistribution wiring layer having a second upper surface and a second lower surface opposite to the second upper surface, the redistribution wiring layer on the substrate structure, and the redistribution wiring layer having a plurality of redistribution wirings,
a plurality of buffer dies on the second upper surface of the redistribution wiring layer and electrically connected to the at least one bridge chip through the plurality of redistribution wirings, and
a plurality of semiconductor chips sequentially stacked on each of the plurality of buffer dies and electrically connected to the plurality of buffer dies.

2. The semiconductor package of claim 1, wherein the semiconductor memory device includes a sealing member that covers the plurality of buffer dies and the plurality of semiconductor chips on the redistribution wiring layer.

3. The semiconductor package of claim 1, wherein the redistribution wiring layer includes:
a plurality of first redistribution pads electrically connected to the plurality of redistribution wirings and exposed from the second upper surface; and
a plurality of second redistribution pads electrically connected to the plurality of redistribution wirings and exposed from the second lower surface.

4. The semiconductor package of claim 3, wherein the redistribution wiring layer further includes a plurality of solder bumps on the plurality of second redistribution pads respectively.

5. The semiconductor package of claim 3, wherein each of the plurality of buffer dies includes a plurality of lower buffer pads that are exposed toward the redistribution wiring layer, and
wherein the plurality of lower buffer pads are bonded to the plurality of first redistribution pads and are electrically connected to the plurality of first redistribution pads.

6. The semiconductor package of claim 1, wherein each of the plurality of buffer dies and the plurality of semiconductor chips include a high bandwidth memory device.

7. The semiconductor package of claim 1, wherein
the substrate structure includes a first number of the at least one bridge chip,
the semiconductor memory device includes a second number of the plurality of buffer dies, and
the first number is smaller than the second number.

8. The semiconductor package of claim 1, wherein in plan view, at least a portion of the semiconductor logic device overlaps at least a portion of the at least one bridge chip.

9. The semiconductor package of claim 1, wherein in plan view, at least a portion of the semiconductor memory device overlaps at least a portion of the at least one bridge chip.

10. The semiconductor package of claim 1, wherein the substrate structure includes:
a semiconductor substrate, and the at least one bridge chip is on the semiconductor substrate;
a plurality of conductive structures on the semiconductor substrate and spaced apart from the at least one bridge chip;
a sealing member covering the at least one bridge chip and the plurality of conductive structures on the semiconductor substrate;
first external connection pads exposed from the sealing member and electrically connected to the at least one bridge chip; and
second external connection pads exposed from the second sealing member and electrically connected to the plurality of conductive structures.

11. A semiconductor package, comprising:
a substrate structure having a first upper surface and a first lower surface opposite to the first upper surface, the substrate structure having at least one bridge chip therein;
a semiconductor logic device mounted on the first upper surface of the substrate structure and electrically connected to the at least one bridge chip; and
a semiconductor memory device on the first upper surface of the substrate structure and spaced apart from the semiconductor logic device, the semiconductor memory device electrically connected to the semiconductor logic device through the at least one bridge chip,
wherein the semiconductor memory device includes
a redistribution wiring layer having a second upper surface and a second lower surface opposite to the second upper surface and having a plurality of redistribution wirings,
a plurality of buffer dies on the second upper surface of the redistribution wiring layer and electrically connected to the at least one bridge chip through the plurality of redistribution wirings, and
a plurality of semiconductor chips sequentially stacked on each of the plurality of buffer dies and electrically connected to the plurality of buffer dies.

12. The semiconductor package of claim 11, wherein the semiconductor memory device includes a sealing member that covers the plurality of buffer dies and the plurality of semiconductor chips on the redistribution wiring layer.

13. The semiconductor package of claim 11, wherein the redistribution wiring layer includes:
a plurality of first redistribution pads electrically connected to the plurality of redistribution wirings and exposed from the second upper surface; and
a plurality of second redistribution pads electrically connected to the plurality of redistribution wirings and exposed from the second lower surface.

14. The semiconductor package of claim 13, wherein the redistribution wiring layer further includes a plurality of solder bumps on the second redistribution pads respectively.

15. The semiconductor package of claim 13, wherein each of the plurality of buffer dies includes a plurality of buffer pads that are exposed toward the redistribution wiring layer, and
the plurality of buffer pads are bonded to the plurality of first redistribution pads and are electrically connected to the plurality of first redistribution pads.

16. The semiconductor package of claim 11, wherein each of the plurality of buffer dies and the plurality of semiconductor chips include a high bandwidth memory device.

17. The semiconductor package of claim 11, wherein
the substrate structure includes a first number of the at least one bridge chip,
the semiconductor memory device includes a second number of the plurality of buffer dies, and
the first number is smaller than the second number.

18. The semiconductor package of claim 11, wherein in plan view, at least a portion of the semiconductor logic device overlaps at least a portion of the at least one bridge chip.

19. The semiconductor package of claim 11, wherein in plan view, at least a portion of the semiconductor memory device overlaps at least a portion of the at least one bridge chip.

20. A semiconductor package, comprising:
a substrate structure having a first upper surface and a first lower surface opposite to the first upper surface, the substrate structure having a bridge chip therein;
a semiconductor memory device on the first upper surface of the substrate structure; and
a semiconductor logic device mounted on the first upper surface of the substrate structure and spaced apart from the semiconductor memory device, and the semiconductor logic device electrically connected to the semiconductor memory device through the bridge chip,
wherein the semiconductor memory device includes
a redistribution wiring layer having a second upper surface and a second lower surface opposite to the second upper surface, the redistribution wiring layer on the substrate structure, and the redistribution wiring layer having a plurality of redistribution wirings,
a plurality of buffer dies on the second upper surface of the redistribution wiring layer and electrically connected to the bridge chip through the plurality of redistribution wirings,
a plurality of semiconductor chips sequentially stacked on each of the plurality of buffer dies and electrically connected to the plurality of buffer dies, and
a sealing member covering the plurality of buffer dies and the plurality of semiconductor chips on the redistribution wiring layer.
